(19) United States
(12) Patent Application Publication
(10) Pub. No.: US 2007/0246700 A1
(43) Pub. Date: Oct. 25, 2007

(54) Light Emitting Device and Method of Manufacturing the Same

(76) Inventor: Hyung Jo Park, Gwangsan-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/739,138

(22) Filed: Apr. 24, 2007

(30) Foreign Application Priority Data
Apr. 25, 2006 (KR) 10-2006-0037149

(51) Int. Cl. H01L 29/06

(52) U.S. Cl. 257/13

(57) ABSTRACT

Provided are embodiments of a light emitting device and a method of manufacturing the same. The light emitting device can include a substrate having a nano-sized structure and a semiconductor light emitting structure on the substrate. The method of manufacturing the light emitting device can include forming a nano-sized structure on the surface of the substrate and forming a first conduction type semiconductor layer, an active layer and a second conduction type semiconductor layer on the substrate.

### CROSS-REFERENCE TO RELATED APPLICATION

The present application claims the benefit under 35 U.S.C. § 119 to Korean Patent Application No. 10-2006-0037149, filed Apr. 25, 2006, which is hereby incorporated by reference in its entirety.

### BACKGROUND

A group III-V nitride semiconductor has been widely applied to light devices such as blue/green light emitting diodes (LEDs), high speed switching devices such as metal oxide semiconductor field effect transistors (MOSFETs) and hetero junction field effect transistors (HJFETs), and light sources of lighting devices and display devices. In particular, a light emitting device using a group III nitride semiconductor has a direct transition-type band gap corresponding to a range of visible rays to ultraviolet rays to realize highly efficient light emission.

The nitride semiconductor is mostly applied in LEDs or laser diodes (LDs). Research to improve a fabrication process or luminous efficiency has been in constant progress.

Gallium Nitride (GaN) is generally used for the group III-V nitride semiconductor. This nitride semiconductor is grown on a substrate through a crystal growth method, activated as p-type semiconductors or n-type semiconductors depending on the dopant, and realized as PN junction devices.

A substrate made of materials such as sapphire (Al₂O₃) single crystal or carbonized silicon (SiC) single crystal is mostly used for the nitride semiconductor. There exists a large lattice mismatch between the substrate and the group III-V nitride semiconductor crystal grown thereon. Research is being carried out to solve the lattice mismatch between the substrate and GaN.

A problem resulting from factors determining the luminous efficiency of an LED is that external photon efficiency may be low. The external photon efficiency is referred to as an efficiency with which light generated from an active layer travels to the outside. At this point, a portion of light is not transmitted at the semiconductor device boundary due to a refractive index difference at the boundary, but is attenuated due to total internal reflection while traveling inside of the device. To solve this problem, numerous methods of improving external photon efficiency have been proposed.

### BRIEF SUMMARY

Embodiments of the present invention provide a light emitting device and a method of manufacturing the same that may maximize output luminous efficiency.

Embodiments of the present invention provide a light emitting device and a method of manufacturing the same, wherein a nano-sized structure is formed on a substrate, and a semiconductor light emitting structure is formed on the nano-sized structure.

An embodiment of the present invention provides a light emitting device comprising: a substrate including a nano-sized structure; and a light emitting structure on the substrate.

Another embodiment of the present invention provides a light emitting device comprising: a substrate including a nano-sized structure having an unevenness pattern; an n-type semiconductor layer on the substrate; an active layer on the n-type semiconductor layer; and a p-type semiconductor layer on the active layer.

An embodiment of the present invention provides a method of manufacturing a light emitting device, the method comprising: forming a nano-sized structure on a substrate; forming a first conduction type semiconductor layer on the substrate; forming an active layer on the first conduction type semiconductor layer; and forming a second conduction type semiconductor layer on the active layer.

### BRIEF DESCRIPTION OF THE DRAWINGS

FIG. 1 is a cross-sectional view illustrating a light emitting device according to an embodiment of the present invention;

FIG. 2 is a top view illustrating a substrate on which a nano structure is formed according to an embodiment of the present invention;

FIG. 3 is a cross-sectional view illustrating photon emission in a light emitting device according to an embodiment of the present invention shown in FIG. 1;

FIGS. 4 to 10 are cross-sectional views illustrating processes of manufacturing a light emitting device according to an embodiment of the present invention;

FIG. 11 is a sectional view illustrating a light emitting device according to an embodiment of the present invention; and

FIG. 12 is a graph comparing output characteristics of nitride semiconductor light emitting devices.

### DETAILED DESCRIPTION

Reference will now be made in detail to the preferred embodiments, examples of which are illustrated in the accompanying drawings.

In the descriptions of referenced embodiments of the present invention, “on” and “under” may include “directly” and “indirectly” when each layer, range, pattern or element are referred to be formed “on” or “under” other layers, ranges, patterns or elements.

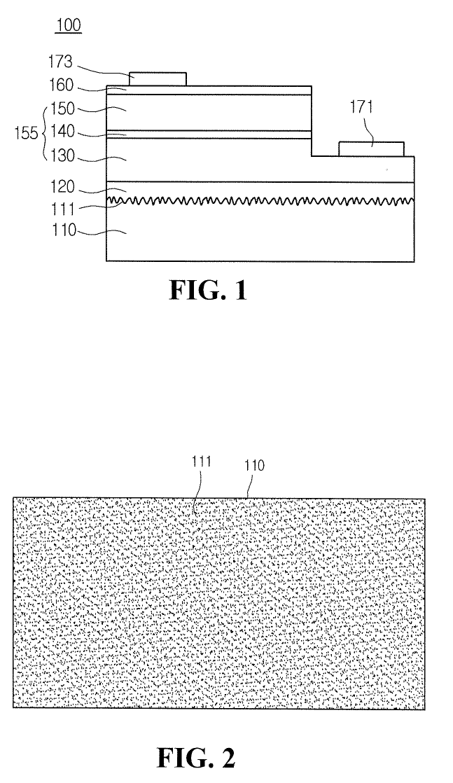

FIG. 1 is a cross-sectional view illustrating an embodiment of the present invention. FIG. 2 is a view illustrating a substrate on which nano-sized structures are formed according to an embodiment of the present invention.

Referring to FIG. 1, a light emitting device 100 can include a substrate 110 in which a nano-sized structure is formed, a buffer layer 120, a first conduction type semiconductor layer 130, an active layer 140 and a second conduction type semiconductor layer 150.

Examples of the substrate 110 can include sapphire, SiC and Si substrates. Referring to FIG. 2, a nano-sized structure 111 (referred to as a nano structure hereinafter) can be formed in the surface of the substrate 110 to affect photons. The nano structure can have at least one side of 100 nanometers or more.

The nano structure 111 can include at least one or a mixture of two or more of SiO₂, Si₃N₄, Ag, Cr, Ni, Au and Pt.

The nano structure 111 can be formed in the surface of the substrate 110 in an uneven pattern, a size of which affects photons. The nano structure 111 may be formed in a random size and/or a random shape on the surface of the substrate 110.

The nano structure 111 can have at least one side of 100 nm or more, and can be formed with high density. In detail, a diameter and/or a height of the nano structure 111 may be about 100˜1000 nm.

Examples of a shape that may be used for the nano structure 111 include a cylindrical shape, a lens shape and a circular or non-circular conical shape.

A light emitting structure 155 may be formed on the substrate 110. The light emitting structure 155 can include an active layer 140 interposed between first and second conduction type semiconductor layers 130 and 150. One or more semiconductor layers may be formed on or under the light emitting structure 155 to increase a lattice match or luminous efficiency.

A buffer layer 120 may be formed on the substrate 110. The buffer layer 120 can serve as a layer decreasing a lattice constant difference between the substrate 110 and the nitride layer. Examples of a structure that may be used for the buffer 120 may include an AlInN structure, an InGaN/GaN superlattice structure, an InGaN/GaN layer structure and an AlInGaN/InGaN/GaN layer structure.

A first conduction type semiconductor layer 130 can be formed on the buffer layer 120. The first conduction type semiconductor layer 130 may be implemented with an n-type GaN layer. The n-type GaN layer may be formed by supplying silane gas (6.3×10⁻⁹ mol/min) including NH₃ (3.7×10⁻² mol/min), TMGa (1.2×10⁻⁴ mol/min) and n-type dopant (e.g., Si), for example.

An undoped nitride layer (not shown) may be formed between the buffer layer 120 and the first conduction type semiconductor layer 130. The undoped nitride layer can be implemented with an undoped GaN layer of a predetermined thickness not including dopant by, for example, supplying NH₃ and TMGa on the buffer layer 120 at a growth temperature of about 1500° C.

In embodiments of the present invention, both, either or neither of the buffer layer 120 and the undoped GaN layer may be formed on the substrate 110.

An active layer of single or multi quantum well structure can be formed on the first conduction type semiconductor layer 130.

The active layer 140 can be formed of InGaN/GaN and can be grown to a thickness of about 120 to 1200 Å by supplying NH₃. TMGa and TMIn using a nitrogen gas as a carrier gas at a growth temperature of about 780° C. The composition of the active layer 140 may vary in its mol ratio of In of InGaN.

A second conduction type semiconductor layer 150 can be formed on the active layer 140. The second conduction type semiconductor layer 150 may be implemented with p-type GaN layer. The p-type GaN layer can be grown to a thickness of hundreds of angstroms to thousands of angstroms by increasing the growth temperature to more than 1000° C. and supplying TMGa and Cp2Mg.

A transparent electrode 160 can be formed on the second conduction type semiconductor layer 150. The transparent electrode 160 can serve as a transparent oxide and may be formed with one or more layers formed of at least one of ITO, ZnO, RuOx, TiOx and IrOx.

A first electrode 171 can be formed on the first conduction type semiconductor layer 130, and a second electrode 173 can be formed on the second conduction type semiconductor layer 150.

A P-N junction structure as well as an N-P junction structure may be provided on substrate 110 as a light emitting structure after a nano structure 111 is formed on the substrate surface.

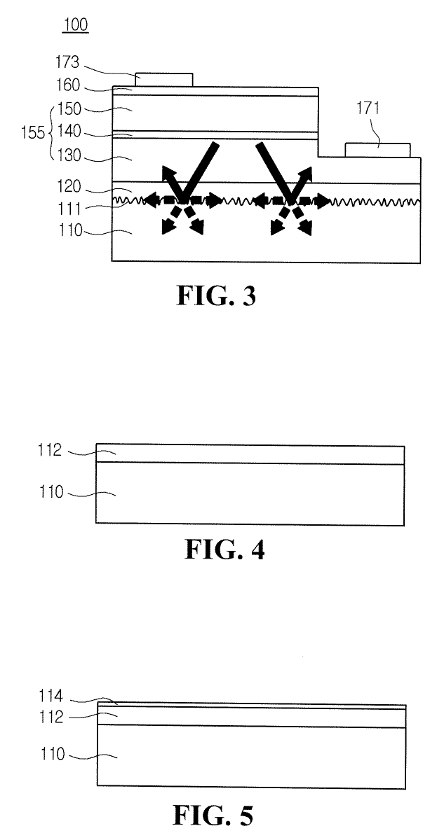

FIG. 3 is a view illustrating a photon propagating into a substrate surface in a light emitting device according to an embodiment of the present invention.

Referring to FIG. 3, when a forward voltage is applied between first and second electrodes 171 and 173 of the light emitting device 100, an electron of the first conduction type semiconductor layer 130 and a hole of the second conduction type semiconductor layer 150 recombine at the active layer 140 to generate a photon, which is emitted to the outside.

Some of the photons emitted from the active layer 140 that propagate into the substrate 110 are refracted or scattered to the outside from colliding with the nano structures 111 formed in the surface of the substrate 110. Accordingly, an output luminous efficiency can be improved by means of the nano structure 111 formed with high density in the surface of the substrate 110. Light emitting characteristics of the light emitting device can be also improved.

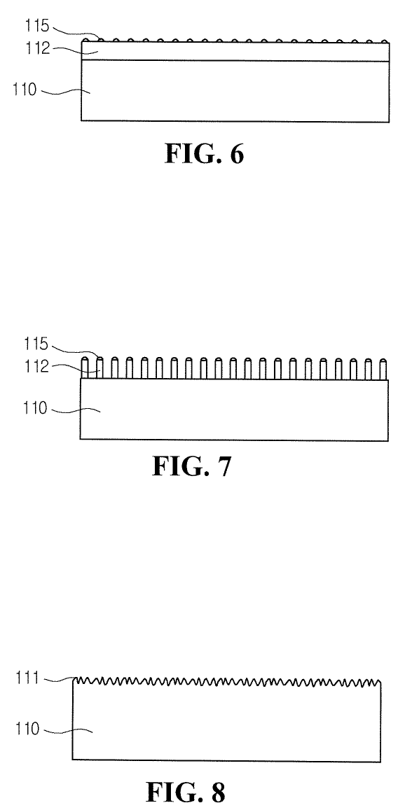

FIGS. 4 to 10 are cross-sectional views illustrating a process of manufacturing a light emitting device according to an embodiment of the present invention.

Referring to FIGS. 4 and 5, mask layers 112 and 114 may be deposited on a substrate 110, but the number of the mask layers is not limited to the number of the mask layers illustrated in this embodiment.

The first mask layer 112 can be deposited as a SiO₂ or Si₃N₄ thin film on the substrate 110 using a plasma enhanced chemical vapor deposition (PECVD) equipment and formed to a thickness of about 100˜2000 nm. For example, in an embodiment, the PECVD equipment can ignite plasma after injecting SiH₄, N₂O and N₂ gases under predetermined conditions to form Si reactive species and 0 reactive species. The two reactive species can combine to deposit the SiO₂ thin film on the substrate 110.

In an embodiment, the second mask layer 114 can be deposited using metal. Examples of a method that may be used for forming the second mask layer 114 include an E-beam evaporator, a thermal evaporator and a sputtering method. The second mask layer 114 may be formed with Ag, Cr, Ni, Au, Pt or an alloy thereof and deposited to a thickness of about 5˜50 nm.

Here, a cleaning process may be performed after the depositing of the first mask layer 112. The cleaning process can be performed before the depositing of the second mask layer 114 or after the deposition of the second mask layer 114. For example, an organic cleaning process may include a sequential process of a treatment with acetone for 5˜10 minutes, a treatment with alcohol for 1˜5 minutes and a deionized (DI) water treatment for 5˜10 minutes.

Referring to FIGS. 5 to 7, a heat treatment process may be performed on the substrate 110 on which the first mask layer 112 and the second mask layer 114 are deposited. The heat treatment process may be performed under the temperature of hundreds of degrees (e.g., in one embodiment at about 300˜600° C.) for tens to hundreds of seconds (e.g., in one embodiment at about 300˜400 seconds). Metal of second mask layer 114 is formed as a cluster 115 of 100˜1000 nm in size on the first mask layer 112 through the heat treatment process.

Herein, metal of the second mask layer 114 is molten at a predetermined temperature, so that the cluster 115 is generated by surface tension of the metal. For example, since metal like Ag is thermally unstable, Ag thin films migrate by a heat treatment process and aggregate circularly with each other, so that individual clusters may be formed.

Patterns of the clusters 115 formed on the first mask layer 112 may be formed in a random size and/or a random shape.

Referring to FIG. 7, the first mask layer 112 can be etched using the patterns of clusters 115 formed on the first mask layer 112. That is, the first mask layer 112 and the clusters 115 can be formed in a nano-rod shape by dry-etching the first mask layer 112 along the patterns of clusters 115. Herein, examples of the dry etching method may include reactive ion etching (RIE).

Referring to FIGS. 7 to 8, the surface of the substrate 110 on which the nano-rod shaped first mask layer 112 and clusters are formed can be etched using high density plasma etching. Examples of a gas used during the high density plasma etching include a reactive gas such as BCl₃, Cl₂, etc and an inert gas such as Ar, N₂, etc. Examples of the plasma etching equipments include inductively coupled plasma (ICP), electron cyclotron resonance (ECR) and hellion.

High density plasma etching (density of 1 OE12˜10E13) performed on the surface of the substrate 110 can have an advantage of fast etching speed, low loss of plasma, and high etching selectivity.

A top-down method of the nano technology may be used for a process for forming a nano structure on the substrate surface in the first embodiment. For example, the top-down method may include forming clusters on a first mask layer 112, etching a second mask layer 114, and etching the surface of a substrate.

Also, a cleaning process may be performed on nano-rods remaining on the surface of the substrate. For example, the cleaning process can be performed on the clusters 115 of the second mask layer 114, and the cleaning process of the first mask layer 112 can be performed. When the metal of the second mask layer 114 is Ag, the cleaning process can be performed using a hydrochloric acid-based material. When the first mask layer 112 is formed of SiO₂, the cleaning process can be performed using a hydrofluoric acid.

When the final etching and cleaning processes are completed as described above, an uneven nano structure 111 can be formed on the surface of the substrate as illustrated in FIG. 8. The nano structure 111 can be referred to as a protrusion having at least one side of more than 100 nm in size when seen three-dimensionally. That is, at least one of the three axes of the protrusion may be more than 100 nm in size. The nano structure 111 can be formed to have a diameter and/or height of about 100˜1000 nm, and may include at least one of a cylindrical shape, a lens shape and a circular or non-circular conical shape.

In an embodiment, a process such as photolithography may be omitted by forming a nano structure on the substrate surface.

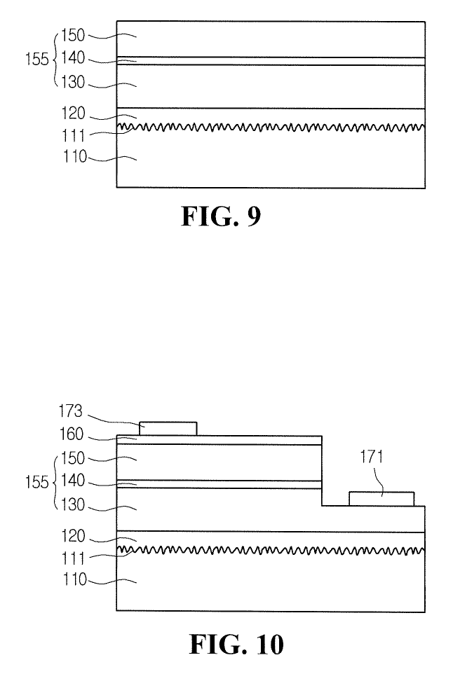

Referring to FIGS. 9 and 10, a buffer layer 120 can be formed on the substrate 110 having the nano structures 111, and a light emitting structure 155 can be formed on the buffer layer 120. The light emitting structure 155 can include a first conduction type semiconductor layer 130, an active layer 140, and a second conduction type semiconductor layer 150. A transparent electrode 160 can be formed on the light emitting structure 155.

Referring to FIG. 10, after a portion of the resulting structure can include the transparent electrode 160 to the first conduction type semiconductor layer 130 is partially etched, a second electrode 173 can be formed on the transparent electrode 160, and a first electrode 171 can be formed on the first conduction type semiconductor layer 130.

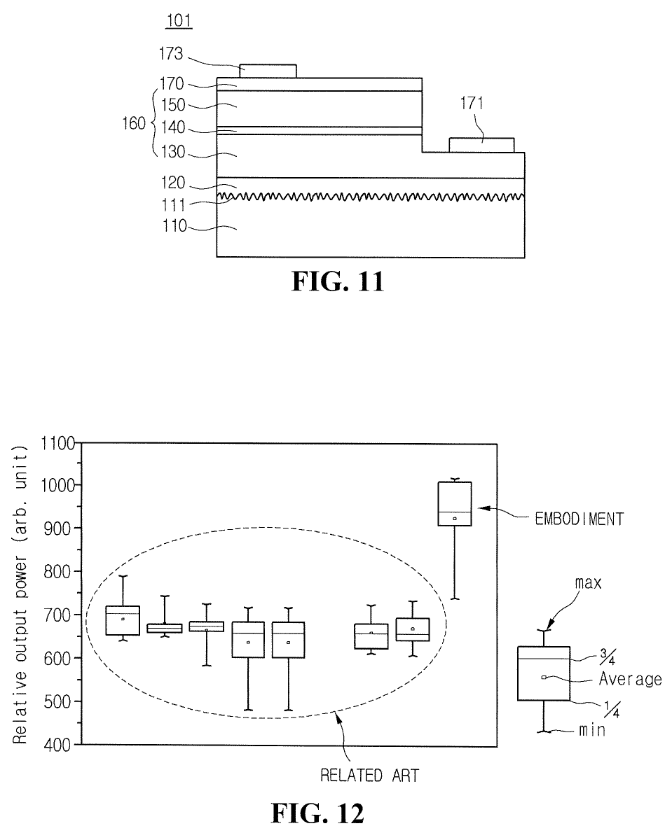

FIG. 11 is a cross-sectional view illustrating a light emitting device according to a second embodiment. The same reference numerals are used for similar elements as those of the first embodiment, descriptions thereof will be briefly made.

Referring to FIG. 11, a light emitting device 101 can include a nano structure 111 formed in the surface of a substrate 110. A buffer layer 120, a first conduction type semiconductor layer 130, an active layer 140, a second conduction type semiconductor layer 150 and a third conductive semiconductor layer 170 are formed on the substrate 110. Herein, a light emitting structure 165 may include the first conduction type semiconductor 130, the active layer 140, the second conduction type semiconductor layer 150, and the third conductive semiconductor layer 170.

The third conductive semiconductor layer 170 may be implemented with an n-type GaN layer. The n-type GaN layer may be formed by supplying silane gas (6.3×10⁻⁹ mol/min) including NH₃ (3.7×10⁻² mol/min), TMGa (1.2×10⁻⁴ mol/min) and n-type dopant (e.g., Si), for example. This n-type GaN layer can be formed to a thickness of tens of nanometers.

After the third conductive semiconductor layer 170 is formed, portions of the third conductive semiconductor layer 170 to the first conduction type semiconductor layer 130 can be partially etched to expose a portion of the first conduction type semiconductor layer 130. The etching process can be performed using anisotropic wet etching.

A first electrode 171 can be formed on the first conduction type semiconductor layer 130, and a second electrode 173 can be formed on the third conductive semiconductor layer 170. The light emitting device may be realized in an npn or pnp junction structure.

FIG. 12 is a view illustrating output characteristics of light emitting devices using box plots. The range of the output characteristics of embodiments of the present invention is from a minimum of 750 to a maximum of 1050, and center and average values are about 950. On the other hand, though output characteristics of related art light emitting devices are different for each type light emitting device, a maximum value is about 800, a minimum value is about 450, and center and average values are in the range of 600˜700. Therefore, it is possible to provide a light emitting device having a higher light output characteristic compared to the plotted related art light emitting devices.

Any reference in this specification to “one embodiment,” “an embodiment,” “example embodiment,” etc., means that a particular feature, structure, or characteristic described in connection with the embodiment is included in at least one embodiment. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a substrate including a photon affecting nano-sized structure; and
a light emitting structure on the substrate.

2. The light emitting device according to claim 1, wherein the substrate is a sapphire, SiC or Si substrate.

3. The light emitting device according to claim 1, wherein the photon affecting nano-sized structure is formed in an uneven shape with a random size or shape on the substrate.

4. The light emitting device according to claim 1, wherein the photon affecting nano-sized structure has a diameter and/or a height of about 100˜1000 nm.

5. The light emitting device according to claim 1, wherein the photon affecting nano-sized structure comprises at least one nano structure of a cylindrical shape, a lens shape or a circular or non-circular conical shape.

6. The light emitting device according to claim 1, wherein the light emitting structure comprises:
a first conduction type semiconductor layer on the substrate;
an active layer on the first conduction type semiconductor layer; and
a second conduction type semiconductor layer on the active layer.

7. The light emitting device according to claim 6, further comprising a buffer layer and/or an undoped nitride layer formed between the substrate and the first conduction type semiconductor layer.

8. The light emitting device according to claim 6, further comprising at least one of a transparent layer and a third conductive semiconductor layer on the second conduction type semiconductor layer.

9. The light emitting device according to claim 1, wherein the photon affecting nano-sized structure comprises at least one or a mixture of two or more of SiO₂, Si₃N₄, Ag, Cr, Ni, Au and Pt.

10. A light emitting device comprising:
a substrate including a photon affecting nano-sized structure having an uneven shape;
an n-type semiconductor layer on the substrate;
an active layer on the n-type semiconductor layer; and
a p-type semiconductor layer on the active layer.

11. The light emitting device according to claim 10, further comprising a buffer layer and/or an undoped nitride layer formed between the substrate and the n-type semiconductor layer.

12. The light emitting device according to claim 10, wherein the photon affecting nano-sized structure is formed to have at least one side of 100 nanometers or more.

13. A method of manufacturing a light emitting device, the method comprising:
forming a photon affecting nano-sized structure on a substrate;
forming a first conduction type semiconductor layer on the substrate;
forming an active layer on the first conduction type semiconductor layer; and
forming a second conduction type semiconductor layer on the active layer.

14. The method according to claim 13, wherein the forming of the photon affecting nano-sized structure comprises:
forming a first mask layer on the substrate;
forming a nano-sized cluster pattern on the first mask layer;
etching the first mask layer using the cluster pattern; and
etching the surface of the substrate using the cluster pattern and the etched first mask layer to form the photon affecting nano-sized structure.

15. The method according to claim 14, wherein the forming of the nano-sized cluster pattern comprises:
forming a second mask layer made of metal on the first mask layer; and
heat-treating the substrate on which the second mask layer has been formed at a predetermined temperature to form a cluster having a size of about 100-1000 nanometers.

16. The method according to claim 15, wherein the first mask layer is formed of a SiO₂ or Si₃N₄ thin film with a thickness of about 100˜2000 nanometers.

17. The method according to claim 16, wherein the second mask layer is one or a mixture of two or more of Ag, Cr, Ni, Au and Pt with a thickness of about 5˜50 nanometers.

18. The method according to claim 15, wherein etching the first mask layer using the cluster pattern comprises performing dry etching.

19. The method according to claim 15, wherein etching the surface of the substrate comprises performing high density plasma etching.

20. The method according to claim 14, further comprising forming at least one of a buffer layer and undoped nitride layer on the substrate.
